(19) United States
(12) Patent Application Publication
(10) Pub. No.: US 2025/0386590 A1
(43) Pub. Date: Dec. 18, 2025

(54) SEMICONDUCTOR DEVICE IN WHICH CHANNEL STRUCTURES ARE OFFSET

(71) Applicant: SAMSUNG ELECTRONICS CO., LTD., Suwon-si (KR)

(72) Inventors: SANGJINE PARK, Suwon-si (KR); YOUNGJUN KIM, Suwon-si (KR)

(73) Assignee: SAMSUNG ELECTRONICS CO., LTD., Suwon-si (KR)

(21) Appl. No.: 19/007,992

(22) Filed: Jan. 2, 2025

(30) Foreign Application Priority Data
Jun. 13, 2024 (KR) 10-2024-0076817

(51) Int. Cl. H10D 84/83; H10D 30/00; H10D 30/01; H10D 30/43; H10D 62/10; H10D 62/13; H10D 64/23; H10D 84/01

(52) U.S. Cl. CPC H10D 84/8311; H10D 30/014; H10D 30/019; H10D 30/43; H10D 30/502; H10D 62/121; H10D 62/151; H10D 64/251; H10D 64/254; H10D 84/0149; H10D 84/0151; H10D 84/8312; H10D 84/83138; H10D 84/832

(57) ABSTRACT

A semiconductor device includes: a lower transistor including a lower channel structure and a lower source/drain structure on the lower channel structure; and an upper transistor above the lower transistor, the upper transistor including an upper channel structure and an upper source/drain structure on the upper channel structure, wherein a portion of the upper channel structure overlaps the lower channel structure in a vertical direction, and another portion of the upper channel structure does not overlap the lower channel structure in the vertical direction.

### CROSS-REFERENCE TO RELATED APPLICATION

This application is based on and claims priority to Korean Patent Application No. 10-2024-0076817 filed on Jun. 13, 2024, in the Korean Intellectual Property Office, the disclosure of which is incorporated herein in its entirety by reference.

### BACKGROUND

### 1. Field

The disclosure relates to a semiconductor device in which a lower channel structure and an upper channel structure are offset from each other.

### 2. Description of the Related Art

Transistors with a reduced size are required to improve density of logic devices in an integrated circuit. To increase density of transistors within a limited space on a substrate, semiconductor devices with a multi-stack structure in which transistors are formed in a lower stack and an upper stack, respectively, are being developed. The above information may be presented as a related art to help with the understanding of the disclosure.

### SUMMARY

Example embodiments of the disclosure provide a semiconductor device in which a lower channel structure of a lower transistor and an upper channel structure of an upper transistor are horizontally offset to provide spaces for contact structures connected to an upper portion of a lower source/drain structure of the lower transistor and a lower portion of an upper source/drain structure of the upper transistor in a high-density footprint, and a method of manufacturing the same.

However, improvement achieved through the example embodiments of the disclosure are not limited to those described above, and additional improvements not mentioned above may also be achieved.

According to an aspect the disclosure, there is provided a semiconductor device which may include: a lower transistor including a lower channel structure and a lower source/drain structure on the lower channel structure; and an upper transistor above the lower transistor, the upper transistor including an upper channel structure and an upper source/drain structure on the upper channel structure, wherein a portion of the upper channel structure overlaps the lower channel structure in a vertical direction, and another portion of the upper channel structure does not overlap the lower channel structure in the vertical direction.

According to an aspect the disclosure, there is provided a semiconductor device which may include: a lower transistor including a lower channel structure and a lower source/drain structure on the lower channel structure; and an upper transistor above the lower transistor, the upper transistor including an upper channel structure and an upper source/drain structure on the upper channel structure, wherein side surfaces of the lower channel structure and vertically corresponding side surfaces of the upper channel structure are offset from each other in a horizontal direction, respectively.

According to another aspect of the disclosure, there is provided a method of manufacturing a semiconductor device. The method may include: forming a lower transistor such that the lower transistor comprises a lower channel structure and a lower source/drain structure on the lower channel structure; and forming an upper transistor above the lower transistor such that the upper transistor comprises an upper channel structure and an upper source/drain structure on the upper channel structure, and wherein the lower channel structure and the upper channel structure are formed such that a portion of the upper channel structure overlaps the lower channel structure in a vertical direction, and another portion of the upper channel structure does not overlap the lower channel structure in the vertical direction.

### BRIEF DESCRIPTION OF DRAWINGS

These and/or other aspects, features, and advantages of certain embodiments in the disclosure will become apparent and more readily appreciated from the following description of embodiments, taken in conjunction with the accompanying drawings of which:

FIG. 1 is a front perspective view illustrating a portion of a semiconductor device, according to one or more embodiments;

FIG. 2 is a rear perspective view illustrating a portion of the semiconductor device of FIG. 1, according to one or more embodiments;

FIG. 3 is a cross-sectional view taken along a line A-A′ of FIG. 1, according to one or more embodiments;

FIG. 4 is a cross-sectional view taken along a line B-B′ of FIG. 2, according to one or more embodiments;

FIG. 5 is a cross-sectional view taken along a line C-C′ of FIG. 2, according to one or more embodiments;

FIG. 6 is a schematic diagram of an inverter circuit formed by a semiconductor device, according to one or more embodiments;

FIG. 7 is a cross-sectional view illustrating a portion of a semiconductor device, according to one or more embodiments;

FIG. 8 is a cross-sectional view illustrating a portion of a semiconductor device, according to one or more embodiments;

FIG. 9 is a flowchart of a method of manufacturing a semiconductor device according to one or more embodiments; and

FIGS. 10 to 18 are sequential cross-sectional views of a stacked mold structure illustrating a process of manufacturing a semiconductor device, according to one or more embodiments.

### DETAILED DESCRIPTION

Hereinafter, embodiments will be described in detail with reference to the accompanying drawings. The embodiments described herein are non-limiting example embodiments, and thus, the disclosure is not limited thereto and may be realized in various other forms. When describing the embodiments with reference to the accompanying drawings, like reference numerals refer to like components, and any repeated description related thereto will be omitted.

The terminology used herein is for the purpose of describing particular embodiments only and is not intended to be limiting. The singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which the embodiments belong. Terms, such as those defined in commonly used dictionaries, are to be interpreted as having a meaning that is consistent with their meaning in the context of the relevant art and the disclosure, and are not to be interpreted in an idealized or overly formal sense unless expressly so defined herein.

When describing the embodiments with reference to the accompanying drawings, like reference numerals refer to like components and a repeated description related thereto will be omitted. In the description of embodiments, detailed description of well-known related structures or functions will be omitted when it is deemed that such description will cause ambiguous interpretation of the disclosure.

Also, in the description of the components, terms such as first, second, A, B, (a), (b) or the like may be used herein when describing components of the disclosure. These terms are used only for the purpose of discriminating one constituent element from another constituent element, and the nature, the sequences, or the orders of the constituent elements are not limited by the terms. It should be noted that if one component is described as being “connected,” “coupled” or “joined” to another component, the former may be directly “connected,” “coupled,” and “joined” to the latter or “connected”, “coupled”, and “joined” to the latter via another component.

The same name may be used to describe an element included in the embodiments described above and an element having a common function. Unless otherwise mentioned, the descriptions of the examples may be applicable to the following examples and thus, duplicated descriptions will be omitted for conciseness.

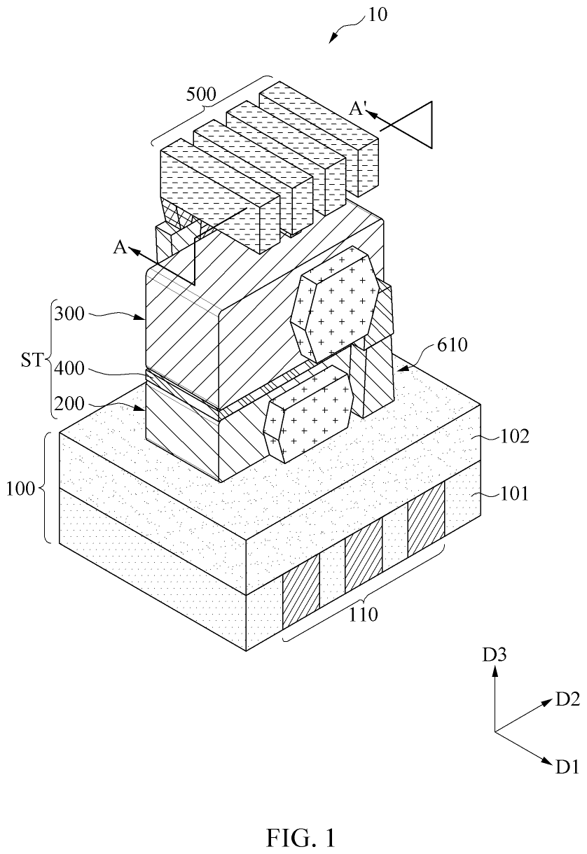

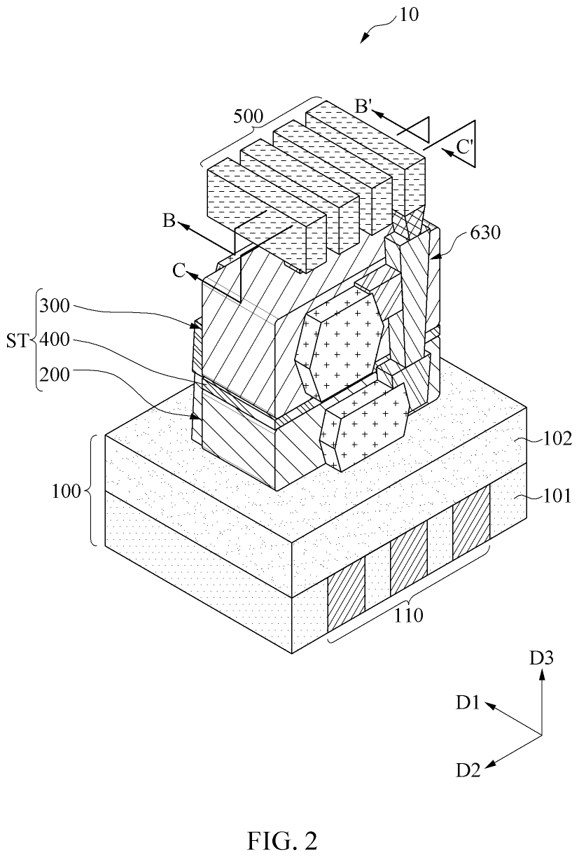

FIG. 1 is a front perspective view illustrating a portion of a semiconductor device, according to one or more embodiments. FIG. 2 is a rear perspective view illustrating a portion of the semiconductor device of FIG. 1, according to one or more embodiments.

Referring to FIGS. 1 and 2, a semiconductor device 10 according to one or more embodiments may include one or more transistor stacks ST formed on a substrate 100. A transistor stack ST may be formed in a structure in which a pair of transistors (e.g., a lower transistor 200 and an upper transistor 300) are stacked in a vertical direction D3. Hereinafter, in describing FIGS. 1 and 2, the semiconductor device 10 will be described using one transistor stack ST as an example for ease of description. In the shown embodiment, a first horizontal direction D1 and a second horizontal direction D2 are horizontal directions that are parallel to a top surface of the substrate 100 and perpendicular to each other. The vertical direction D3 is a direction perpendicular to the first horizontal direction D1 and the second horizontal direction D2. Meanwhile, it will be obvious to one of ordinary skill in the art that areas shown as empty spaces in FIGS. 1 and 2 may be filled with an insulator, an air gap, or other structures may be positioned therein.

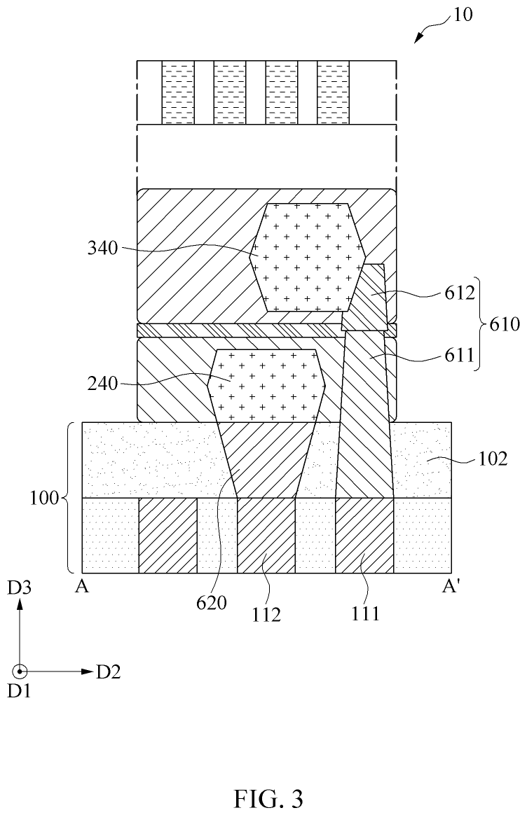

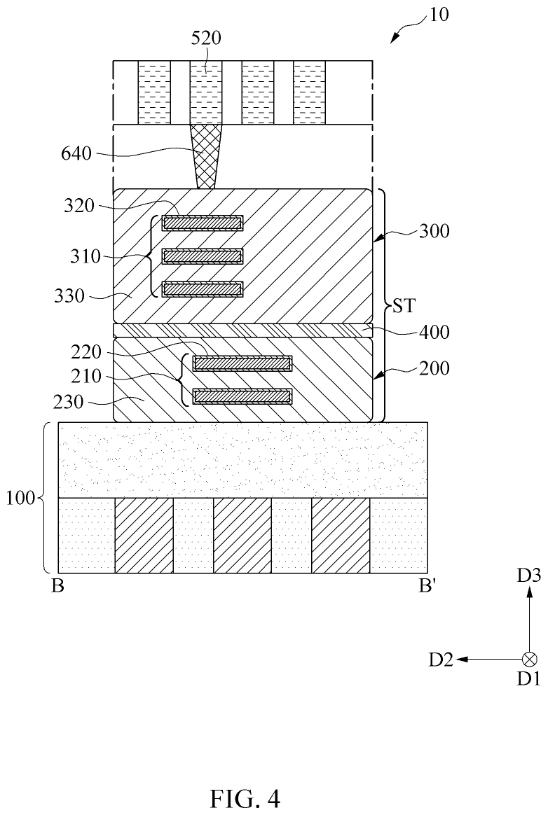

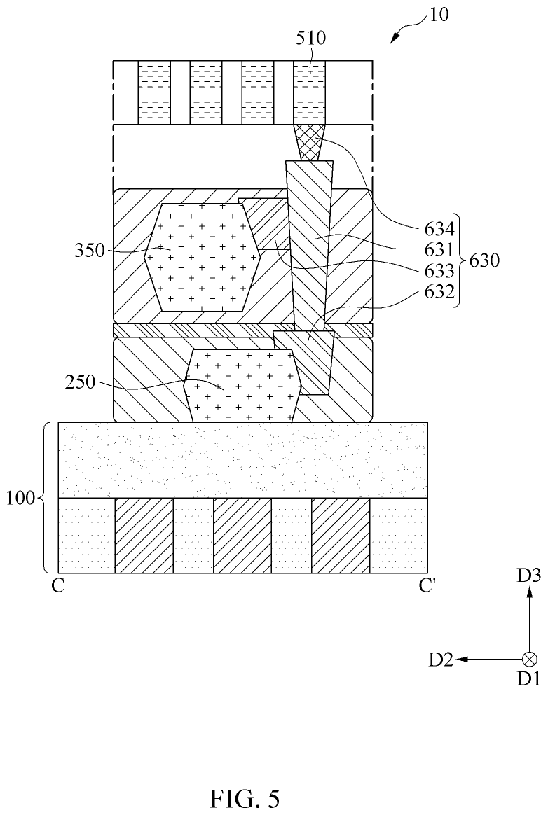

The semiconductor device 10 according to one or more embodiments may include a substrate 100, a transistor stack ST formed on the substrate 100, a lower wiring line 110, an upper wiring line 500, and a plurality of contact structures (e.g. a first contact structure 610 of FIG. 3, a second contact structure 620 of FIG. 3, a third contact structure 630 of FIG. 5, and a fourth contact structure 640 of FIG. 4). The substrate 100 may be a bulk substrate formed of a semiconductor material, such as a silicon (Si), silicon-germanium (SiGe), or silicon-on-insulator (SOI) substrate. Alternatively, the substrate 100 may be an insulating substrate including an insulating material. For example, the insulating substrate may include at least one of silicon oxide, silicon nitride, silicon oxynitride, silicon carbide, or any other low-k dielectric material. However, this is an example, and the type of substrate is not limited thereto.

The transistor stack ST may include a lower transistor 200, an intermediate insulating layer 400, and an upper transistor 300. The lower transistor 200 may be positioned on the substrate 100. The upper transistor 300 may be positioned above the lower transistor 200. The intermediate insulating layer 400 may be positioned between the lower transistor 200 and the upper transistor 300. In one example transistor stack ST, the lower transistor 200 may be an n-type field-effect transistor (nFET), and the upper transistor 300 may be a p-type field-effect transistor (pFET). In another example transistor stack ST, the lower transistor 200 may be a pFET, and the upper transistor 300 may be an nFET. In still another example transistor stack ST, the lower transistor 200 and the upper transistor 300 may each be a pFET or an nFET.

The lower wiring line 110 may be positioned below the lower transistor 200. The lower wiring line 110 may be provided in plurality. The plurality of lower wiring lines 110 may extend in the first horizontal direction D1, and may be spaced apart from each other in the second horizontal direction D2. The number of lower wiring lines 110 shown in the drawings is an example, and the number of lower wiring lines 110 is not limited thereto. For example, the plurality of lower wiring lines 110 may include at least a first lower wiring line (e.g., 111 of FIG. 3) and a second lower wiring line (e.g., 112 of FIG. 3).

For example, the lower wiring line 110 may be a line for transmitting power. For example, the lower wiring line 110 may be a power line 110, and the power line 110 may include a first power line (e.g., 111 of FIG. 3) and a second power line (e.g., 112 of FIG. 3). As another example, one of the plurality of lower wiring lines may be a signal line connected to another circuit element for transmitting a signal other than being connected to a voltage source, while the others are power lines connected to respective voltage sources. As still another example, all of the plurality of lower wiring lines may be signal lines. Hereinafter, the description will be provided based on the lower wiring line 110 which is the power line 110.

The power line 110 may be formed in a backside power delivery network (BSPDN) structure. For example, the power line 110 may be formed on the substrate 100. For example, the substrate 100 may include a first lower insulating layer 101 and a second lower insulating layer 102 stacked on the first lower insulating layer 101, and a plurality of power lines 110 may be formed in the first lower insulating layer 101. However, this is an example, and the structure of the substrate 100 is not limited thereto.

The upper wiring line 500 may be positioned on an opposite side of the substrate 100 in the vertical direction D3 based on the transistor stack ST. The upper wiring line 500 may be positioned above the upper transistor 300. The upper wiring line 500 may be provided in plurality. The plurality of upper wiring lines 500 may extend in the first horizontal direction D1, and may be spaced apart from each other in the second horizontal direction D2. The number of upper wiring lines 500 shown in the drawings is an example, and the number of upper wiring lines 500 is not limited thereto. For example, the plurality of upper wiring lines 500 may include at least a first upper wiring line (e.g., 510 of FIG. 5) and a second upper wiring line (e.g., 520 of FIG. 4).

For example, the upper wiring line 500 may be a line for transmitting a signal. For example, the upper wiring line 500 may be a signal line 500, and the signal line 500 may include a first signal line (e.g., 510 of FIG. 5) and a second signal line (e.g., 520 of FIG. 4). However, as another example, at least one of the upper wiring lines may be a power line. As still another example, all of the plurality of upper wiring lines may be power lines.

Hereinafter, the description will be provided based on the upper wiring line 500 which is the signal line 500.

The power line 110 and the signal line 500 may be positioned opposite to each other with the transistor stack ST therebetween in the vertical direction D3. For example, the power line 110 may be positioned below the transistor stack ST, and the signal line 500 may be formed above the transistor stack ST in the vertical direction D3. By separating positions of the power line 110 and the signal line 500 connected to one transistor stack ST in the vertical direction D3, a required area in the horizontal direction (e.g., the second horizontal direction D2) to connect the power line 110 and the signal line 500 to the transistor stack ST may be reduced.

FIG. 3 is a cross-sectional view taken along a line A-A′ of FIG. 1, according to one or more embodiments. FIG. 4 is a cross-sectional view taken along a line B-B′ of FIG. 2, according to one or more embodiments. FIG. 5 is a cross-sectional view taken along a line C-C′ of FIG. 2, according to one or more embodiments.

Hereinafter, components of the semiconductor device 10 according to one or more embodiments will be described with reference to FIGS. 1 to 5.

The lower transistor 200 may include a plurality of lower channel layers 210 as a channel structure, a plurality of lower gate insulating layers 220, a lower gate structure 230, a first lower source/drain structure 240, and a second lower source/drain structure 250.

The plurality of lower channel layers 210 may function as current flow channels of the lower transistor 200. For example, the plurality of lower channel layers 210 may include silicon (Si). For example, a lower channel layer 210 may be formed as a nanosheet. The plurality of lower channel layers 210 may be spaced apart from each other in the vertical direction D3. For example, the plurality of lower channel layers 210 may have substantially the same width (e.g., a width in the second horizontal direction D2). For example, the plurality of lower channel layers 210 may be aligned with each other in the vertical direction D3. The number and/or width of lower channel layers 210 shown in the drawings are examples, and the number and/or width of lower channel layers 210 are not limited thereto.

Each of the lower channel layers 210 may be surrounded by the lower gate insulating layer 220. The lower gate insulating layer 220 may be formed on a bottom surface, a top surface, and both side surfaces of each of the lower channel layers 210. The lower gate insulating layer 220 may include an insulating material. For example, the lower gate insulating layer 220 may include silicon oxide (SiO), silicon nitride (SiN), silicon oxynitride (SiON), and/or a high-k material with a high dielectric constant compared to silicon oxide, but is not limited thereto. The high-k material may include, for example, one or more of boron nitride, hafnium oxide, hafnium silicon oxide, hafnium aluminum oxide, lanthanum oxide, lanthanum aluminum oxide, zirconium oxide, and zirconium silicon oxide.

The lower gate structure 230 may surround the plurality of lower channel layers 210. The lower gate structure 230 may extend in the first horizontal direction D1 and the second horizontal direction D2. The lower gate structure 230 may include a conductive material. For example, the lower gate structure 230 may be formed of a plurality of films including a work function metal film and a gate electrode film. For example, the work function metal film may include titanium (Ti), tantalum (Ta), or a compound thereof, and the gate electrode film may include copper (Cu), aluminum (Al), tungsten (W), molybdenum (Mo), ruthenium (Ru) or compounds thereof. However, this is an example, and the material included in the lower gate structure 230 is not limited thereto.

The first lower source/drain structure 240 and the second lower source/drain structure 250 may be connected to both end portions in the first horizontal direction D1 of the plurality of lower channel layers 210, respectively. For example, the first lower source/drain structure 240 may be connected to one lateral portion in the first horizontal direction D1 (e.g., a portion in the +D1 direction) of the plurality of lower channel layers 210, and the second lower source/drain structure 250 may be connected to the other lateral portion in the first horizontal direction (e.g., a portion in the −D direction) of the plurality of lower channel layers 210. The plurality of lower channel layers 210 may extend in the first horizontal direction D1 between the first lower source/drain structure 240 and the second lower source/drain structure 250. The first lower source/drain structure 240 and the second lower source/drain structure 250 may be obtained by epitaxial growth of the plurality of lower channel layers 210. When the semiconductor device 10 is viewed in the first horizontal direction D1, the first lower source/drain structure 240 and the second lower source/drain structure 250 may be formed at positions corresponding to the plurality of lower channel layers 210. The first lower source/drain structure 240 and the second lower source/drain structure 250 may each be connected to the power line 110 or the signal line 500.

The upper transistor 300 may include a plurality of upper channel layers 310 as a channel structure, a plurality of upper gate insulating layers 320, an upper gate structure 330, a first upper source/drain structure 340, and a second upper source/drain structure 350.

The plurality of upper channel layers 310 may function as current flow channels of the upper transistor 300. For example, the plurality of upper channel layers 310 may include silicon (Si). For example, an upper channel layer 310 may be formed as a nanosheet. The plurality of upper channel layers 310 may be spaced apart from each other in the vertical direction D3. For example, the plurality of upper channel layers 310 may have substantially the same width (e.g., a width in the second horizontal direction D2). For example, the plurality of upper channel layers 310 may be aligned with each other in the vertical direction D3. The number of upper channel layers 310 and the number of lower channel layers 210 may be the same or different. For example, the upper channel layers 310 may be formed to have a narrower width than the lower channel layers 210 in the second horizontal direction D2 while the number of the upper channel layers 310 is greater than that of the lower channel layers 210, and heights of the channel layers 210 and 310 are the same. This structure of the channel layers 210 and 310 may be implemented to achieve the same effective channel width, that is, a sum of channel widths, in each of the lower transistor 200 and the upper transistor so that these two transistors can have the same device performance in terms of an amount of current flow in a unit time. However, this is an example, and the upper channel layers 310 and the lower channel layers 210 may have substantially the same width or similar widths in the second horizontal direction D2 to achieve a semiconductor device in which the lower transistor 200 and the upper transistor 300 have different channel performances. The number and/or width of upper channel layers 310 shown in the drawings are examples, and the number and/or width of upper channel layers 310 are not limited thereto.

Each of the upper channel layers 310 may be surrounded by the upper gate insulating layer 320. The upper gate insulating layer 320 may be formed on a bottom surface, a top surface and both side surfaces of each of the upper channel layers 310. The upper gate insulating layer 320 may include an insulating material. For example, the upper gate insulating layer 320 may include silicon oxide (SiO), silicon nitride (SiN), silicon oxynitride (SiON), and/or a high-k material with a high dielectric constant compared to silicon oxide, but is not limited thereto. The high-k material may include, for example, one or more of boron nitride, hafnium oxide, hafnium silicon oxide, hafnium aluminum oxide, lanthanum oxide, lanthanum aluminum oxide, zirconium oxide, and zirconium silicon oxide.

The upper gate structure 330 may surround the plurality of upper channel layers 310. The upper gate structure 330 may extend in the first horizontal direction D1 and the second horizontal direction D2. The upper gate structure 330 may include a conductive material. For example, the upper gate structure 330 may be formed of a plurality of films including a work function metal film and a gate electrode film. For example, the work function metal film may include titanium (Ti), tantalum (Ta), or a compound thereof, and the gate electrode film may include copper (Cu), aluminum (Al), tungsten (W), molybdenum (Mo), ruthenium (Ru) or compounds thereof. However, this is an example, and the material included in the upper gate structure 330 is not limited thereto. The upper gate structure 330 and the lower gate structure 230 may include different materials depending on a work function.

The upper gate structure 330 may be stacked above the lower gate structure 230. The intermediate insulating layer 400 may be positioned between the upper gate structure 330 and the lower gate structure 230. For example, the upper gate structure 330 and the lower gate structure 230 may be separated by the intermediate insulating layer 400. The intermediate insulating layer 400 may include an insulating material. For example, the intermediate insulating layer 400 may be formed of silicon oxide (SiO), silicon nitride (SiN), and/or silicon oxynitride (SiON), but is not limited thereto. The upper gate structure 330 and the lower gate structure 230 may be electrically connected to each other by a separate structure (e.g., an interconnector) that is not shown.

The first upper source/drain structure 340 and the second upper source/drain structure 350 may be connected to both end portions in the first horizontal direction D1 of the plurality of upper channel layers 310, respectively. For example, the first upper source/drain structure 340 may be connected to one lateral portion in the first horizontal direction D1 (e.g., a portion in the +D1 direction) of the plurality of upper channel layers 310, and the second upper source/drain structure 350 may be connected to the other lateral portion in the first horizontal direction (e.g., a portion in the −D direction) of the plurality of upper channel layers 310. The plurality of upper channel layers 310 may extend in the first horizontal direction D1 between the first upper source/drain structure 340 and the second upper source/drain structure 350. The first upper source/drain structure 340 and the second upper source/drain structure 350 may be obtained by epitaxial growth of the plurality of upper channel layers 310. When the semiconductor device 10 is viewed in the first horizontal direction D1, the first upper source/drain structure 340 and the second upper source/drain structure 350 may be formed at positions corresponding to the plurality of upper channel layers 310. The first upper source/drain structure 340 and the second upper source/drain structure 350 may each be connected to the power line 110 or the signal line 500.

In one transistor stack ST, as shown in FIG. 4, the plurality of lower channel layers 210 and the plurality of upper channel layers 310 may be positioned to be offset from each other in the second horizontal direction D2. Here, being offset may refer to a state of being misaligned and skewed. For example, as shown in FIG. 4, the plurality of lower channel layers 210 may be offset in the −D2 direction with respect to the plurality of upper channel layers 310. Meanwhile, as another example, the plurality of lower channel layers 210 may be offset in the +D2 direction with respect to the plurality of upper channel layers 310.

A virtual vertical center-line of the plurality of lower channel layers 210 and a virtual vertical center-line of the plurality of upper channel layers 310 may be misaligned with each other in the vertical direction D3. The plurality of lower channel layers 210 and the plurality of upper channel layers 310 may only partially overlap in the vertical direction D3. For example, a partial area (e.g., a partial area in the −D2 direction) of the plurality of upper channel layers 310 may overlap the plurality of lower channel layers 210 in the vertical direction D3, and the other partial area (e.g., a partial area in the +D2 direction) of the plurality of upper channel layers 310 may not overlap the plurality of lower channel layers 210 in the vertical direction D3. As another example, a partial area (e.g., a partial area in the +D2 direction) of the plurality of lower channel layers 210 may overlap the plurality of upper channel layers 310 in the vertical direction D3, and the other partial area (e.g., a partial area in the −D2 direction) of the plurality of lower channel layers 310 may not overlap the plurality of upper channel layers 210 in the vertical direction D3.

One lateral end portion in the second horizontal direction D2 (e.g., an end portion in the +D2 direction) of the plurality of lower channel layers 210 and one lateral end portion in the second horizontal direction D2 (e.g., an end portion in the +D2 direction) of the plurality of upper channel layers 310 may be misaligned with each other in the vertical direction D3. For example, the one lateral end portion in the second horizontal direction D2 (e.g., the end portion in the +D2 direction) of the plurality of upper channel layers 310 may be positioned to protrude more in the +D2 direction than the one lateral end portion in the second horizontal direction D2 (e.g., the end portion in the +D2 direction) of the plurality of lower channel layers 210. The one lateral end portion in the second horizontal direction D2 (e.g., the end portion in the +D2 direction) of the plurality of lower channel layers 210 may overlap the plurality of upper channel layers 310 in the vertical direction D3.

The other lateral end portion in the second horizontal direction D2 (e.g., an end portion in the −D2 direction) of the plurality of lower channel layers 210 and the other lateral end portion in the second horizontal direction D2 (e.g., an end portion in the −D2 direction) of the plurality of upper channel layers 310 may be misaligned with each other in the vertical direction D3. For example, the other lateral end portion in the second horizontal direction D2 (e.g., the end portion in the −D2 direction) of the plurality of lower channel layers 210 may be positioned to protrude more in the −D2 direction than the other lateral end portion in the second horizontal direction D2 (e.g., the end portion in the −D2 direction) of the plurality of upper channel layers 310. The other lateral end portion in the second horizontal direction D2 (e.g., the end portion in the −D2 direction) of the plurality of upper channel layers 310 may overlap the plurality of lower channel layers 210 in the vertical direction D3.

When the plurality of lower channel layers 210 and the plurality of upper channel layers 310 in one transistor stack ST are positioned to be offset from each other in the second horizontal direction D2, the first lower source/drain structure 240 and the first upper source/drain structure 340 may also be positioned to be offset from each other in the second horizontal direction D2 (see FIG. 3), and the second lower source/drain structure 250 and the second upper source/drain structure 350 may also be positioned to be offset from each other in the second horizontal direction D2 (see FIG. 5). For example, as shown in FIG. 3, the first lower source/drain structure 240 (e.g., left and right side edges or surfaces thereof) may be offset in the −D2 direction with respect to the first upper source/drain structure 340 (e.g., left and right side edges or surfaces thereof). As another example, as shown in FIG. 5, the second lower source/drain structure 250 (e.g., left and right side edges or surfaces thereof) may be offset in the −D2 direction with respect to the second upper source/drain structure 350 (e.g., left and right side edges or surfaces thereof). Meanwhile, as still another example, the first lower source/drain structure 240 may be offset in the +D2 direction with respect to the first upper source/drain structure 340, and the second lower source/drain structure 250 may be offset in the +D2 direction with respect to the upper source/drain structure 350.

The plurality of contact structures 610, 620, 630, and 640 may connect the lower transistor 200 and/or the upper transistor 300 to the power line 110 and/or the signal line 500. Each of the plurality of contact structures 610, 620, 630, and 640 may include a conductive material. For example, each of the plurality of contact structures 610, 620, 630, and 640 may be formed of a metal material, such as cobalt (Co), tungsten (W), ruthenium (Ru), or combinations thereof, but is not limited thereto.

The plurality of contact structures 610, 620, 630, and 640 may include a first contact structure 610, a second contact structure 620, a third contact structure 630, and a fourth contact structure 640.

Referring to FIG. 3, the first contact structure 610 may connect the first upper source/drain structure 340 to the first power line 111. The first contact structure 610 may extend in the vertical direction D3 between the first upper source/drain structure 340 and the first power line 111. The first contact structure 610 may extend in the vertical direction D3 from the first power line 111 and directly contact the first upper source/drain structure 340. For example, the first contact structure 610 may include a first through via 611 and a first contact pad 612. Each of the first through via 611 and the first contact pad 612 may include a conductive material. For example, the conductive material may include aluminum (Al), tungsten (W), titanium (Ti), copper (Cu), tantalum (Ta), molybdenum (Mo), ruthenium (Ru), or combinations thereof. However, the conductive material is not limited thereto. For example, the first through via 611 and the first contact pad 612 may include different materials. The first through via 611 may be formed in the vertical direction D3 and connected to the first power line 111. For example, a width of the first through via 611 may decrease from bottom toward top (e.g., in the +D3 direction). The first contact pad 612 may connect the first through via 611 to the first upper source/drain structure 340. The first contact pad 612 may be formed to directly contact the first upper source/drain structure 340. For example, the first contact pad 612 may be connected to a lower portion of the first upper source/drain structure 340. As another example, the first contact pad 612 may be formed by expanding an upper end portion of the first through via 611 in a width direction. However, these are examples, and the structure of the first contact structure 610 is not limited thereto. For example, the first contact structure 610 may include only the first through via 611 that extends from the first power line 111 in the vertical direction D3, and the first through via 611 may directly contact the lower portion of the upper source/drain structure 340. For example, the first contact pad 612 may contact a side surface of the first upper source/drain structure 340. Alternatively, the first contact pad 612 may contact both a bottom surface and a side surface of the first upper source/drain structure 340. For example, the maximum length in the vertical direction D3 of the first contact pad 612 may be greater than the maximum length in the second horizontal direction D2 of the first contact pad 612.

As the first upper source/drain structure 340 is positioned to be offset in the second horizontal direction D2 with respect to the first lower source/drain structure 240, the first upper source/drain structure 340 may be directly connected to the first power line 111 through the first contact structure 610 formed in the vertical direction D3. For example, as shown in FIG. 3, when the first upper source/drain structure 340 is positioned to be offset in the +D2 direction with respect to the first lower source/drain structure 240, a space for forming the first contact structure 610 may be provided below the first upper source/drain structure 340. The first contact structure 610 formed in the vertical direction D3 may be formed in the lower space in the +D2 direction of the first upper source/drain structure 340, and the first upper source/drain structure 340 may be directly connected to the first power line 111 through the first contact structure 610 having only a structure in the vertical direction D3. According to this structure, the first contact structure 610 may connect the first upper source/drain structure 340 and the first power line 111 to each other in the vertical direction D3, without needing to include a separate bypass structure in a horizontal direction (e.g., the second horizontal direction D2) and interfering with the other structure (e.g., the first lower source/drain structure 240). Since the first contact structure 610 may not include a separate bypass structure in the horizontal direction (e.g., the second horizontal direction D2), it is possible to further reduce a pitch in the horizontal direction (e.g., the second horizontal direction D2) of the semiconductor device 10 and to improve integration of the semiconductor device 10.

Referring to FIG. 3, the second contact structure 620 may connect the first lower source/drain structure 240 to the second power line 112. The second contact structure 620 may include a conductive material. For example, the conductive material may include aluminum (Al), tungsten (W), titanium (Ti), copper (Cu), tantalum (Ta), molybdenum (Mo), ruthenium (Ru), or combinations thereof. However, the conductive material is not limited thereto. For example, the second contact structure 620 may extend in the vertical direction D3 from the first lower source/drain structure 240 toward the second power line 112. For example, the second contact structure 620 may penetrate through the second lower insulating layer 102 in the vertical direction D3. For example, a width of the second contact structure 620 may decrease from top toward bottom (e.g., in the −D3 direction). However, this is an example, and the structure of the second contact structure 620 is not limited thereto. For example, the second contact structure 620 may be formed in a structure including a through via and a contact pad. For example, the width of the second contact structure 620 may increase from top toward bottom (e.g., in the −D3 direction).

Referring to FIG. 5, the third contact structure 630 may connect the second lower source/drain structure 250 and the second upper source/drain structure 350 to the first signal line 510 positioned above the transistor stack ST. The third contact structure 630 may be positioned not to overlap the first contact structure (610 of FIG. 3) in the first horizontal direction D1. The third contact structure 630 may include a second through via 631, a second contact pad 632, a third contact pad 633, and a fourth contact pad 634. The second through via 631, the second contact pad 632, the third contact pad 633, and the fourth contact pad 634 may include a conductive material. For example, the conductive material may include aluminum (Al), tungsten (W), titanium (Ti), copper (Cu), tantalum (Ta), molybdenum (Mo), ruthenium (Ru), or combinations thereof. However, the conductive material is not limited thereto. For example, the second through via 631 and the second contact pad 632, the third contact pad 633, or the fourth contact pad 634 may include different materials. The second contact pad 632 may be formed to directly contact the second lower source/drain structure 250. The third contact pad 633 may be formed to directly contact the second upper source/drain structure 350. The fourth contact pad 634 may be formed to directly contact the first signal line 510. The second through via 631 may be formed in the vertical direction D3 to be connected to all the second contact pad 632, the third contact pad 633, and the fourth contact pad 634. For example, a lower end portion of the second through via 631 may be connected to the second contact pad 632, a lateral portion of the second through via 631 may be connected to the third contact pad 633, and an upper end portion of the second through via 631 may be connected to the fourth contact pad 634. However, this is an example, and the structure of the third contact structure 630 is not limited thereto. For example, the second through via 631 may be formed so that the lateral portion of the second through via 631 may directly contact the second upper source/drain structure 350 without a medium of a contact pad (e.g., the third contact pad 633). For example, the second through via 631 may be formed such that the lower end portion of the second through via 631 may directly contact the second lower source/drain structure 250 without a medium of a contact pad (e.g., the second contact pad 632). For example, the second through via 631 may be formed such that the upper end portion of the second through via 631 may directly contact the first signal line 510 without a medium of a contact pad (e.g., the fourth contact pad 634).

Referring to FIG. 4, the fourth contact structure 640 may connect the upper gate structure 330 to the second signal line 520 positioned above the transistor stack ST. For example, the fourth contact structure 640 may extend in the vertical direction D3 from the second signal line 520 toward the upper gate structure 330. For example, the fourth contact structure 640 may connect the second signal line 520 and the upper gate structure 330 in the vertical direction D3. For example, a width of the fourth contact structure 640 may decrease from top toward bottom (e.g., in the −D3 direction). However, this is an example, and the structure of the fourth contact structure 640 is not limited thereto. For example, the fourth contact structure 640 may be formed in a structure including a through via and a contact pad. In another embodiment, the fourth contact structure 640 may be configured to connect the lower gate structure 230 to the second signal line 520. Meanwhile, since the upper gate structure 330 and the lower gate structure 230 may be electrically connected to each other, the upper gate structure 330 and the lower gate structure 230 may be electrically connected to the second signal line 520 directly or indirectly through the fourth contact structure 640.

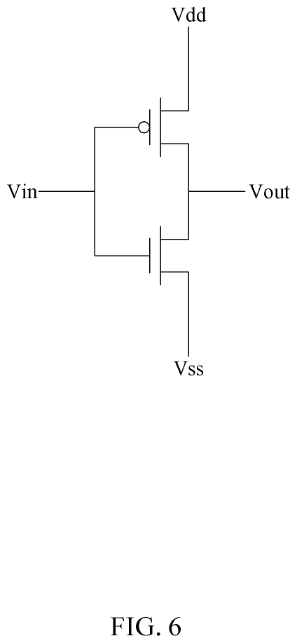

FIG. 6 is a schematic diagram of an inverter circuit formed by a semiconductor device according to one or more embodiments.

Referring to FIG. 6, a semiconductor device (e.g., the semiconductor device 10 of FIGS. 1 to 5) according to one or more embodiments may form an inverter circuit. The inverter circuit of FIG. 6 may include a pFET and an nFET connected in series. To connect the inverter circuit to a power source and other circuit elements, source nodes of the pFET and the nFET may each be connected to a positive voltage source Vdd and a negative voltage source Vss, and drain nodes of the pFET and the nFET may be merged to be connected to the other circuit elements based on a common gate input signal.

The pFET and the nFET shown in FIG. 6 may be formed by the upper transistor 300 and the lower transistor 200 shown in FIGS. 1 to 5. For example, in FIGS. 1 to 5, the upper transistor 300 and the lower transistor 200 may form a pFET and an nFET, respectively. In this case, the first power line 111, the second power line 112, the first signal line 510, and the second signal line 520 may be understood as the positive voltage source Vdd, the negative voltage source Vss, an input line Vin, and an output line Vout, respectively. However, this is an example, and the upper transistor 300 and the lower transistor 200 may form an nFET and a pFET, respectively. In this case, the first power line 111, the second power line 112, the first signal line 510, and the second signal line 520 may be understood as the negative voltage source Vss, the positive voltage source Vdd, the input line Vin, and the output line Vout, respectively.

Meanwhile, the inverter circuit shown in FIG. 6 may be an example of various logic circuits that can be implemented with a semiconductor device (e.g., the semiconductor device 10 of FIGS. 1 to 5) according to one or more embodiments. For example, the semiconductor device 10 may be implemented by various logic circuits, by configuring a plurality of contact structures (e.g., the first contact structure 610 of FIG. 3, the second contact structure 620 of FIG. 3, the third contact structure 630 of FIG. 5, and the fourth contact structure 640 of FIG. 4) in different connections.

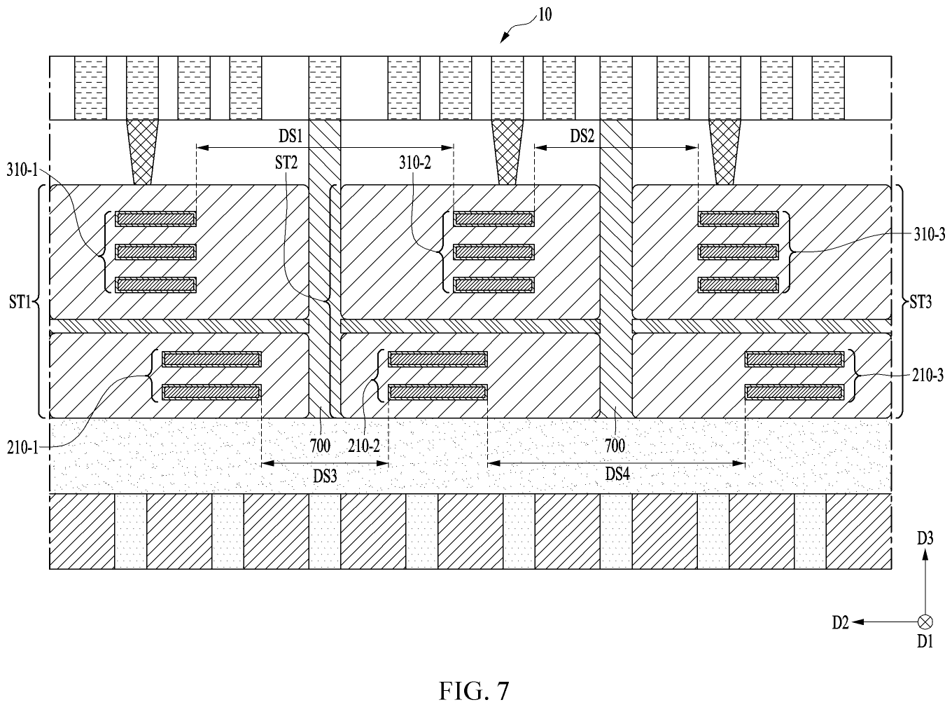

FIG. 7 is a cross-sectional view illustrating a portion of a semiconductor device, according to one or more embodiments. FIG. 7 may be a cross-sectional view at a position corresponding to FIG. 4.

Referring to FIG. 7, the semiconductor device 10 according to one or more embodiments may include a plurality of transistor stacks ST1, ST2, and ST3. Each of the plurality of transistor stacks ST1, ST2, and ST3 may include a lower transistor (e.g., the lower transistor 200 of FIG. 4), an intermediate insulating layer (e.g., the intermediate insulating layer 400 of FIG. 4), and an upper transistor (e.g., the upper transistor 300 of FIG. 4). The plurality of transistor stacks ST1, ST2, and ST3 may be serially arranged side by side in the second horizontal direction D2. A gate cut structure 700 may be positioned between each pair of the plurality of transistor stacks ST1, ST2, and ST3. The gate cut structure 700 may isolate the plurality of transistor stacks ST1, ST2, and ST3 from each other. The gate cut structure 700 may be formed of silicon nitride, silicon oxide, or a composite thereof, not being limited thereto.

The plurality of transistor stacks ST1, ST2 and ST3 may have the same structure dimensions including a width in the second horizontal direction D2, for example. As another example, however, the plurality of transistor stacks ST1, ST2 and ST3 may have different structure dimensions including the width in the second horizontal direction D2. Further, the plurality of gate cut structures 700 may have the same structural dimension including a width in the second horizontal direction D2, for example. However, as another example, the plurality of gate cut structures 700 may have different structural dimension including the width in the second horizontal direction D2.

As shown in FIG. 7, the plurality of transistor stacks ST1, ST2, and ST3 may include at least a first transistor stack ST1, a second transistor stack ST2, and a third transistor stack ST3, for example. The first transistor stack ST1, the second transistor stack ST2, and the third transistor stack ST3 may be serially arranged adjacent to each other and side by side in the second horizontal direction D2.

Among the plurality of transistor stacks ST1, ST2, and ST3, transistor stacks positioned adjacent to each other may be formed symmetrically with respect to the vertical direction D3. For example, among the plurality of transistor stacks ST1, ST2, and ST3, transistor stacks positioned adjacent to each other may be formed symmetrically based on the gate cut structure 700 positioned therebetween. For example, the first transistor stack ST1 and the second transistor stack ST2 may be formed symmetrically with respect to the vertical direction D3. For example, the second transistor stack ST2 and the third transistor stack ST3 may be formed symmetrically with respect to the vertical direction D3.

A direction in which a plurality of lower channel layers 210-1 and a plurality of upper channel layers 310-1 are offset from each other in the first transistor stack ST1 may be opposite to a direction in which a plurality of lower channel layers 210-2 and a plurality of upper channel layers 310-2 are offset from each other in the second transistor stack ST1. For example, as shown in FIG. 7, when the plurality of lower channel layers 210-2 are offset in the +D2 direction with respect to the plurality of upper channel layers 310-2 in the second transistor stack ST2, the plurality of lower channel layers 210-1 may be offset in the −D2 direction with respect to the plurality of upper channel layers 310-1 in the first transistor stack ST1.

Likewise, a direction in which a plurality of lower channel layers 210-3 and a plurality of upper channel layers 310-3 are offset from each other in the third transistor stack ST3 may be opposite to the direction in which the plurality of lower channel layers 210-2 and the plurality of upper channel layers 310-2 are offset from each other in the second transistor stack ST1. For example, as shown in FIG. 7, when the plurality of lower channel layers 210-2 are offset in the +D2 direction with respect to the plurality of upper channel layers 310-2 in the second transistor stack ST2, the plurality of lower channel layers 210-3 may be offset in the −D2 direction with respect to the plurality of upper channel layers 310-3 in the third transistor stack ST3.

For example, a separation distance DS3 in the second horizontal direction D2 between the plurality of lower channel layers 210-1 of the first transistor stack ST1 and the plurality of lower channel layers 210-2 of the second transistor stack ST2 may be smaller than a separation distance DS1 in the second horizontal direction D2 between the plurality of upper channel layers 310-1 of the first transistor stack ST1 and the plurality of upper channel layers 310-2 of the second transistor stack ST2. For example, a separation distance DS4 in the second horizontal direction D2 between the plurality of lower channel layers 210-2 of the second transistor stack ST2 and the plurality of lower channel layers 210-3 of the third transistor stack ST3 may be greater than a separation distance DS2 in the second horizontal direction D2 between the plurality of upper channel layers 310-2 of the second transistor stack ST2 and the plurality of upper channel layers 310-3 of the third transistor stack ST3. For example, the separation distance DS1 in the second horizontal direction D2 between the plurality of upper channel layers 310-1 of the first transistor stack ST1 and the plurality of upper channel layers 310-2 of the second transistor stack ST2 may be greater than the separation distance DS2 in the second horizontal direction D2 between the plurality of upper channel layers 310-2 of the second transistor stack ST2 and the plurality of upper channel layers 310-3 of the third transistor stack ST3. For example, the separation distance DS3 in the second horizontal direction D2 between the plurality of lower channel layers 210-1 of the first transistor stack ST1 and the plurality of lower channel layers 210-2 of the second transistor stack ST2 may be smaller than the separation distance DS4 in the second horizontal direction D2 between the plurality of lower channel layers 210-2 of the second transistor stack ST2 and the plurality of lower channel layers 210-3 of the third transistor stack ST3. For example, the separation distance DS1 in the second horizontal direction D2 between the plurality of upper channel layers 310-1 of the first transistor stack ST1 and the plurality of upper channel layers 310-2 of the second transistor stack ST2 may be greater than or substantially the same as the separation distance DS4 in the second horizontal direction D2 between the plurality of lower channel layers 210-2 of the second transistor stack ST2 and the plurality of lower channel layers 210-3 of the third transistor stack ST3. For example, the separation distance DS2 in the second horizontal direction D2 between the plurality of upper channel layers 310-2 of the second transistor stack ST2 and the plurality of upper channel layers 310-3 of the third transistor stack ST3 may be greater than or substantially the same as the separation distance DS3 in the second horizontal direction D2 between the plurality of lower channel layers 210-1 of the first transistor stack ST1 and the plurality of lower channel layers 210-2 of the second transistor stack ST2. However, this is an example, and each distance between components is not limited thereto.

For example, as shown in FIG. 7, a first-type transistor stack (e.g., ST1 or ST3) and a second-type transistor stack (e.g., ST2), having opposite offset directions of channel layers, may be arranged alternately in the second horizontal direction D2.

Herein, the separation distance may refer to a horizontal distance between a right side surface (or edge) of a channel layer in a transistor stack and a left side surface (or edge) of a channel layer at a same level in the vertical direction in an adjacent transistor stack in the second horizontal direction. For example, the separation distance DS1 may refer to a horizontal distance between a right side surface (or edge) of the uppermost channel layer of the plurality of upper channel layers 310-1 in the first transistor stack ST1 and a left side surface (or edge) of the uppermost channel layer of the plurality of upper channel layers 310-2 in the second transistor stack ST2.

In the drawing, for ease of description, three transistor stacks ST1, ST2, and ST3 are illustrated as an example, but one of ordinary skill in the art may easily understood that the semiconductor device 10 may include four or more transistor stacks arranged side by side in the second horizontal direction D2 and that a pair of transistor stacks (e.g., ST1 and ST2 or ST2 and ST3) arranged adjacent to each other in the second horizontal direction D2 may be formed symmetrically with respect to the vertical direction D3.

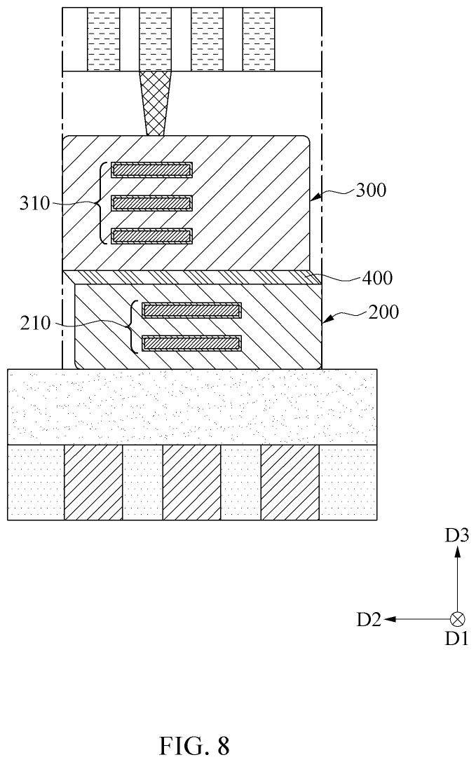

FIG. 8 is a cross-sectional view illustrating a portion of a semiconductor device, according to one or more embodiments. FIG. 8 may be a cross-sectional view at a position corresponding to FIG. 4.

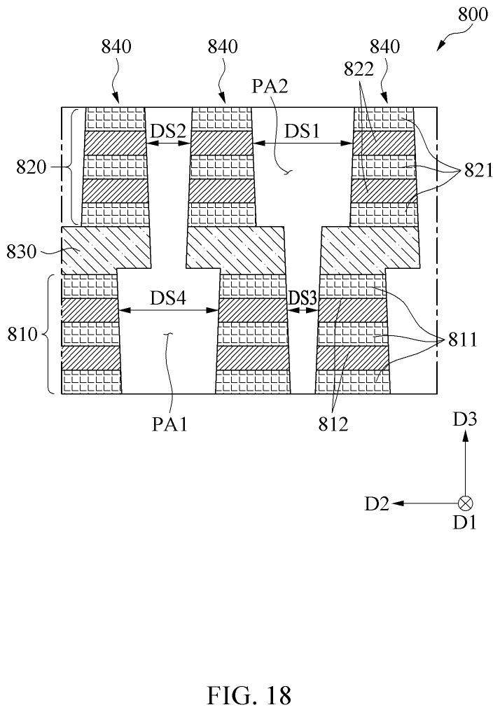

Referring to FIG. 8, in one or more embodiments, both side surfaces, facing the second horizontal direction D2, of the intermediate insulating layer 400 positioned between the lower transistor 200 and the upper transistor 300 may be formed as inclined surfaces. For example, both side surfaces, facing the second horizontal direction D2, of the intermediate insulating layer 400 may be formed to be slanted from the vertical direction or inclined downward from the plurality of upper channel layers 310 toward the plurality of lower channel layers 210. For example, both side surfaces, facing the second horizontal direction D2, of the intermediate insulating layer 400 may be formed to be inclined downward in the direction (e.g., the −D2 direction) in which the plurality of lower channel layers 210 are offset in the second horizontal direction D2 with respect to the plurality of upper channel layers 310. For example, as shown in FIG. 8, when the plurality of lower channel layers 210 are offset in the −D2 direction with respect to the plurality of upper channel layers 310, both side surfaces, facing the second horizontal direction D2, of the intermediate insulating layer 400 may be formed to be inclined downward. This may be understood as cutting both side surfaces in the second horizontal direction D2 of the intermediate insulating layer 400 (or an intermediate insulating layer 830 of FIG. 18) at an angle to be inclined surfaces, because the plurality of lower channel layers 210 and the plurality of upper channel layers 310 are offset from each other in the second horizontal direction D2, during the process of manufacturing the lower transistor 200, the intermediate insulating layer 400, and the upper transistor 300.

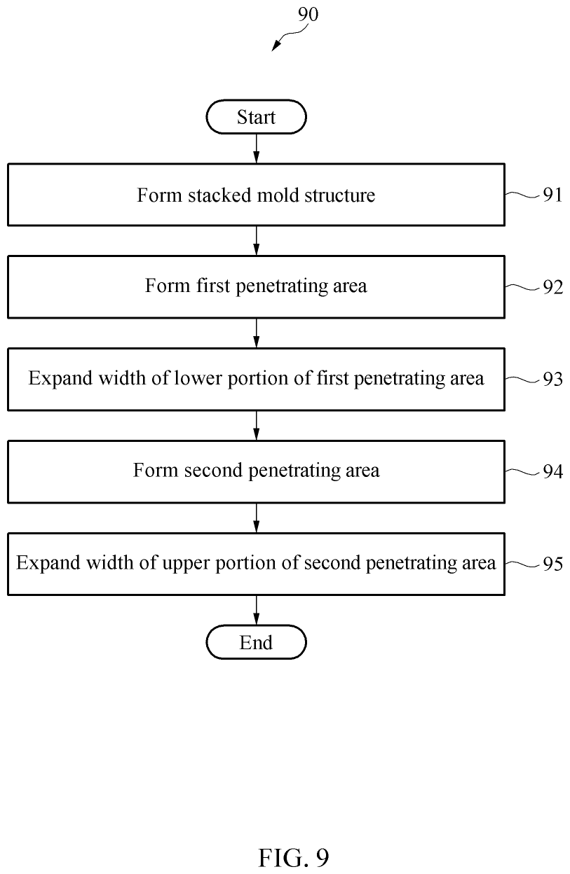

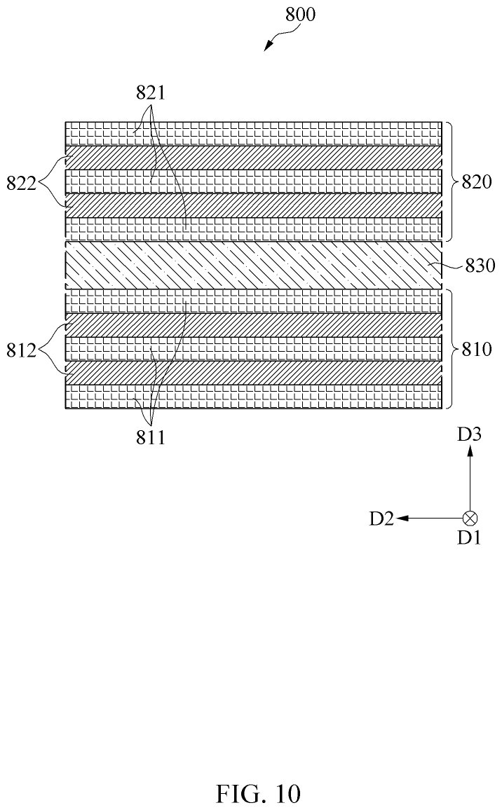

FIG. 9 is a flowchart of a method of manufacturing a semiconductor device, according to one or more embodiments. FIGS. 10 to 18 are sequential cross-sectional views of a stacked mold structure illustrating a process of manufacturing a semiconductor device, according to one or more embodiments.

A method 90 of manufacturing a semiconductor device according to one or more embodiments may be construed as a method of manufacturing the semiconductor device 10 described with reference to FIGS. 1 to 5.

Referring to FIG. 9, the method 90 of manufacturing a semiconductor device may include operation 91 of forming a stacked mold structure, operation 92 of forming a first penetrating area, operation 93 of expanding the width of a lower portion of the first penetrating area, operation 94 of forming a second penetrating area, and operation 95 of expanding the width of an upper portion of the second penetrating area. Meanwhile, FIG. 9 is an example, and the sequence of the method 90 of manufacturing a semiconductor device is not limited thereto. In one or more embodiments, the method 90 of manufacturing a semiconductor device may be performed in a different order than that in the example shown in FIG. 9. At least one of the operations of the method 90 of manufacturing a semiconductor device may be omitted. At least two of the operations of the method 90 of manufacturing a semiconductor device may be performed simultaneously. At least one of the operations of the method 90 of manufacturing a semiconductor device may be performed iteratively.

Hereinafter, the method 90 of manufacturing a semiconductor device will be described with reference to FIGS. 9 to 18.

Operation 91 may be an operation of forming a stacked mold structure 800 (see FIG. 10). As shown in FIG. 10, the stacked mold structure 800 may include a lower stacked structure 810, an intermediate sacrificial layer 830, and an upper stacked structure 820. For example, the lower stacked structure 810, the intermediate sacrificial layer 830, and the upper stacked structure 820 may be sequentially stacked in the vertical direction D3. The lower stacked structure 810 may include a plurality of lower sacrificial layers 811 and a plurality of lower channel layers 812 that are alternately stacked on each other. The upper stacked structure 820 may include a plurality of upper sacrificial layers 821 and a plurality of upper channel layers 822 that are alternately stacked on each other. The intermediate sacrificial layer 830 may be positioned between the lower stacked structure 810 and the upper stacked structure 820.

For example, the plurality of lower channel layers 812 and the plurality of upper channel layers 822 may include a silicon (Si) material. For example, the plurality of lower sacrificial layers 811 and the plurality of upper sacrificial layers 821 may include a silicon-germanium (SiGe) material. For example, the intermediate sacrificial layer 830 may include a silicon-germanium (SiGe) material having a different germanium concentration from those of the plurality of lower sacrificial layers 811 and the plurality of upper sacrificial layers 821. For example, the intermediate sacrificial layer 830 may have a higher germanium concentration than the plurality of lower sacrificial layers 811 and the plurality of upper sacrificial layers 821. This difference in the germanium concentration may enable selective etching of the intermediate sacrificial layer 830 against the sacrificial layers 811 and 821.

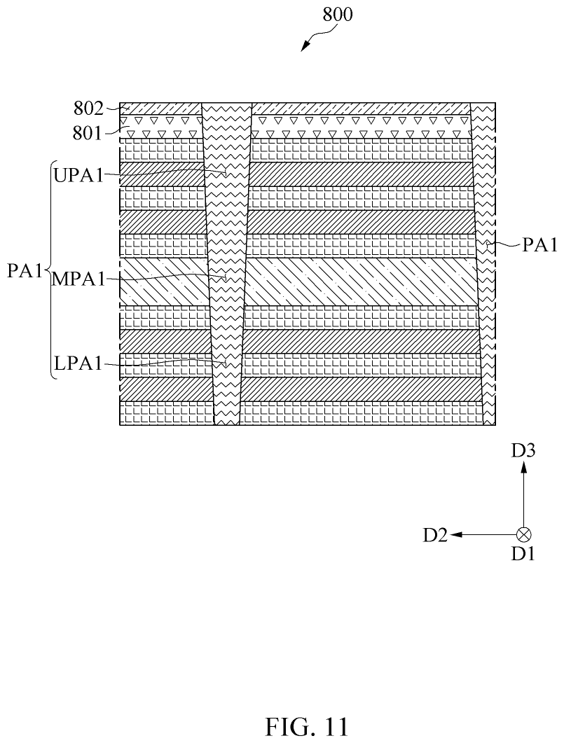

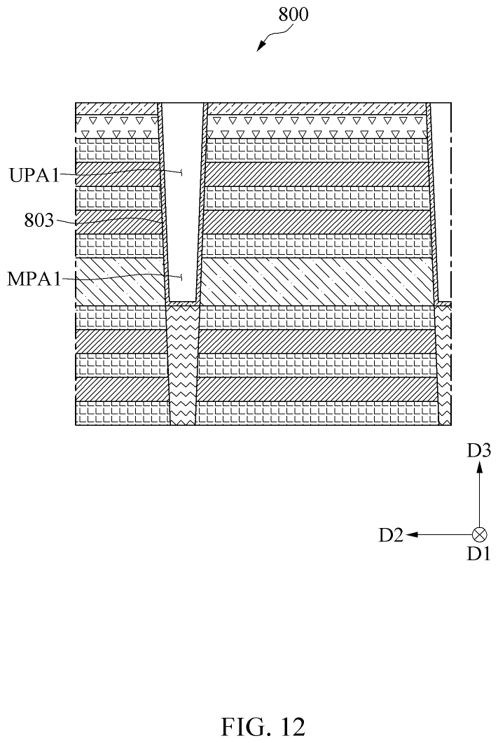

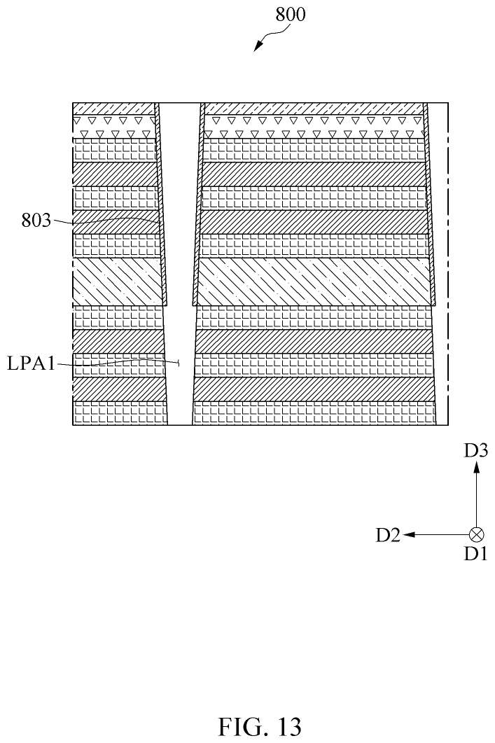

Operation 92 may be an operation of forming a plurality of first penetrating areas PA1 that penetrate through the stacked mold structure 800 at a plurality of first positions (see FIGS. 11 to 13). For example, the plurality of first positions may be spaced apart at designated intervals in the second horizontal direction D2. As shown in FIG. 11, a protective insulating layer 801 and a first protective liner 802 may be formed on the stacked mold structure 800, and the plurality of first penetrating areas PA1 that penetrate through the stacked mold structure 800 in the vertical direction D3 may be formed at the plurality of first positions by an etching process. A first penetrating area PA1 may include a first lower penetrating area LPA1, a first middle penetrating area MPA1, and a first upper penetrating area UPA1. The first lower penetrating area LPA1 may be understood as an area that penetrates through the lower stacked structure 810, the first middle penetrating area MPA1 may be understood as an area that penetrates through the intermediate sacrificial layer 830, and the first upper penetrating area UPA1 may be understood as an area that penetrates through the upper stacked structure 820. The open first penetrating area PA1 may be filled with an insulating material. Thereafter, as shown in FIG. 12, the insulating material in the first middle penetrating area MPA1 and the first upper penetrating area UPA1 may be removed through a partial etching process. A second protective liner 803 may be formed on an inner wall of the first middle penetrating area MPA1 and the first upper penetrating area UPA1. Thereafter, as shown in FIG. 13, the insulating material in the bottom portion of the second protective liner 803 and the first lower penetrating area LPA1 may be removed by an etching process and/or a pullback process.

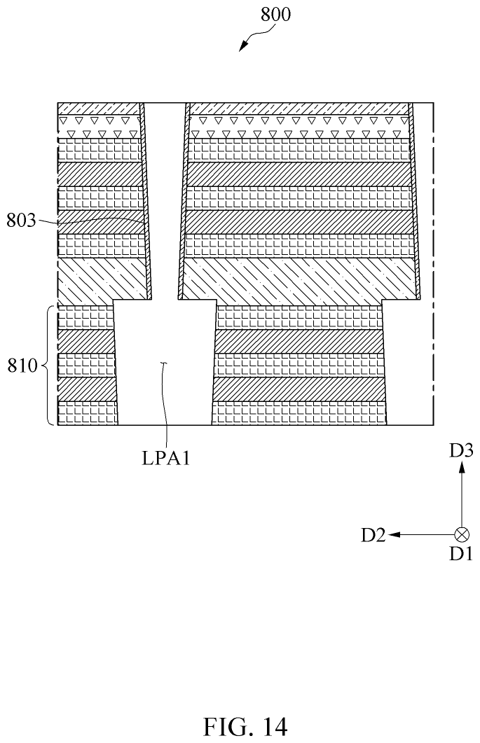

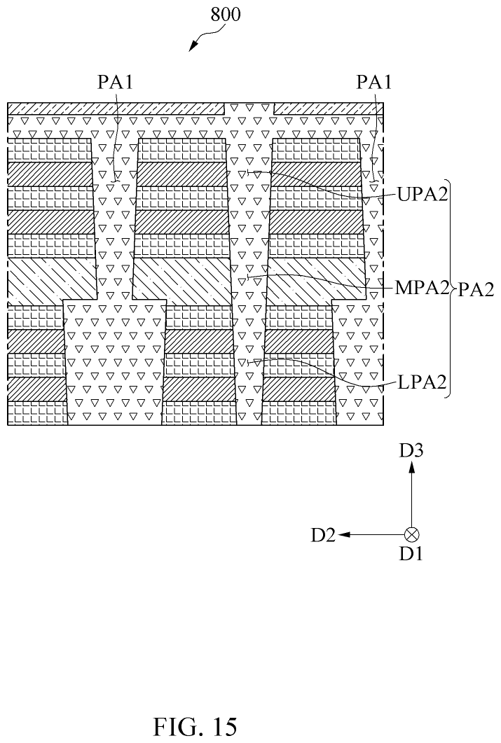

Operation 93 may be an operation of etching the lower stacked structure 810 in a horizontal direction (e.g., the second horizontal direction D2) to expand a width of a lower area (e.g., the first lower penetrating area LPA1) of each of the plurality of first penetrating areas PA1 (see FIG. 14). As shown in FIG. 14, a portion of the lower stacked structure 810 may be removed in the horizontal direction by a horizontal etching process, whereby a width of the first lower penetrating area LPA1 may be expanded. Thereafter, as shown in FIG. 15, the second protective liner 803 may be removed, and the open first penetrating area PA1 may be filled with an insulating material.

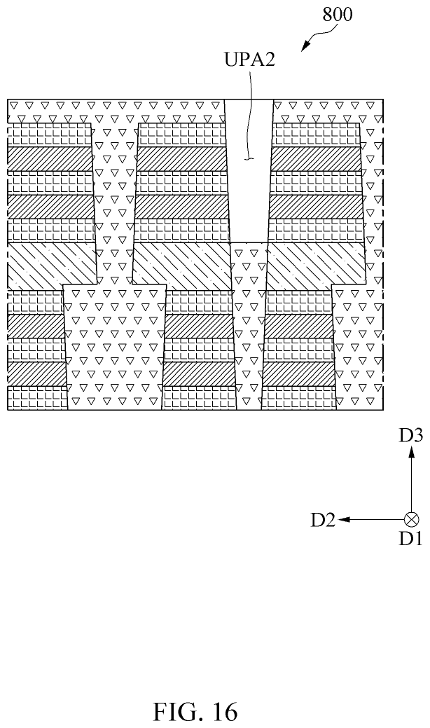

Operation 94 may be an operation of forming a plurality of second penetrating areas PA2 that penetrate through the stacked mold structure 800 at a plurality of second positions respectively interposed between pairs of the plurality of first positions (see FIGS. 15 and 16). For example, each of the plurality of second positions may be interposed between two first positions adjacent thereto. For example, the plurality of second positions may be spaced apart at designated intervals in the second horizontal direction D2. As shown in FIG. 15, the plurality of second penetrating areas PA2 that penetrate through the stacked mold structure 800 in the vertical direction D3 may be formed through an etching process at the plurality of second positions. Each of the plurality of second penetrating areas PA2 may be formed between two first penetrating areas PA1 adjacent thereto. A second penetrating area PA2 may include a second lower penetrating area LPA2, a second middle penetrating area MPA2, and a second upper penetrating area UPA2. The second lower penetrating area LPA2 may be understood as an area that penetrates through the lower stacked structure 810, the second middle penetrating area MPA2 may be understood as an area that penetrates through the intermediate sacrificial layer 830, and the second upper penetrating area UPA2 may be understood as an area that penetrates through the upper stacked structure 820. The open second penetrating area PA2 may be filled with an insulating material. Thereafter, as shown in FIG. 16, the insulating material in the second upper penetrating area UPA2 may be removed through a partial etching process.

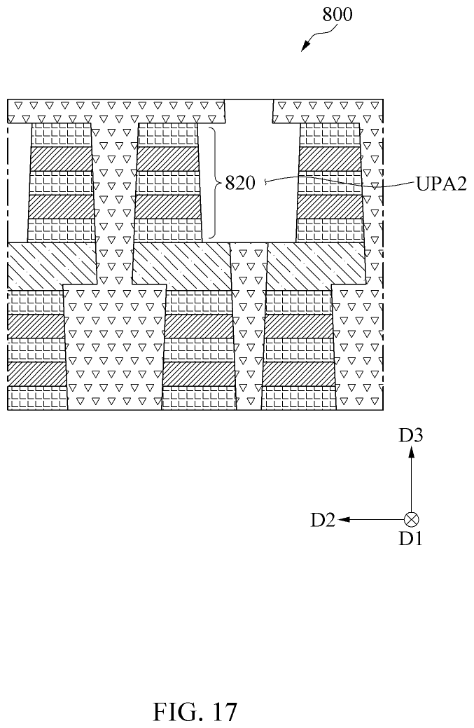

Operation 95 may be an operation of etching the upper stacked structure 820 in a horizontal direction (e.g., the second horizontal direction D2) to expand a width of an upper area (e.g., the second upper penetrating area UPA2) of each of the plurality of second penetrating areas PA2 (see FIG. 17). As shown in FIG. 17, a portion of the upper stacked structure 820 may be removed in the horizontal direction by a horizontal etching process, whereby a width of the second upper penetrating area UPA2 may be expanded. Thereafter, as shown in FIG. 18, the insulating material in the first penetrating area PA1 and the second penetrating area PA2 may be all removed.

Referring to FIG. 18, the stacked mold structure 800 may be separated into a plurality of unit structures 840 spaced apart from each other by the first penetrating area PA1 and the second penetrating area PA2. For example, as shown in FIG. 18, the plurality of unit structures 840 may be spaced apart from each other in the second horizontal direction D2. Adjacent unit structures 840 of the plurality of unit structures 840 may be symmetrical with respect to the vertical direction D3. In each of the plurality of unit structures 840, the lower stacked structure 810 and the upper stacked structure 820 may be positioned to be offset in the horizontal direction D2 based on the intermediate sacrificial layer 830. In each of the plurality of unit structures 840, the plurality of lower channel layers 812 and the plurality of upper channel layers 822 may be positioned to be offset from each other in the second horizontal direction D2.

Through a subsequent process, one unit structure 840 may form one transistor stack (e.g., the transistor stack ST of FIG. 4). For example, the lower stacked structure 810 of the unit structure 840 may form the lower transistor 200 of FIG. 4, and the upper stacked structure 820 of the unit structure 840 may form the upper transistor 300 of FIG. 4. For example, the intermediate sacrificial layer 830 may be removed and then replaced to form the intermediate insulating layer 400 of FIG. 4. For example, the plurality of lower channel layers 812 and the plurality of upper channel layers 822 may form the plurality of lower channel layers 210 and the plurality of upper channel layers 310 of FIG. 4, respectively. For example, the plurality of lower sacrificial layers 811 and the plurality of upper sacrificial layers 821 may be removed and then replaced to form the lower gate structure 230 and the upper gate structure 330 of FIG. 4, respectively. For example, processes of forming source/drain structures, contact structures, power lines, and/or signal lines may be further performed. For example, the separation distances DS1, DS2, DS3, and DS4 in the second horizontal direction D2 respectively between the upper channel layers 310 and the lower channel layers 210 of the unit structures 840 may satisfy the size relationship between the separation distances DS1, DS2, DS3, and DS4 described with reference to FIG. 7.

A number of embodiments have been described above. Nevertheless, it should be understood that various modifications and variations may be made to these embodiments. For example, suitable results may be achieved if the described techniques are performed in a different order, and/or if components in a described system, architecture, device, or circuit are combined in a different manner, and/or replaced or supplemented by other components or their equivalents.

In the above embodiments, the structural difference between the lower channel structure and the upper channel structure and between the lower source/drain structure and the upper source/drain structure of a nanosheet transistor are described. However, the disclosure is not limited thereto, and thus, these structural differences may apply to other types of transistor such as a fin field-effect transistor (FinFET), a forksheet transistor, etc., not being limited thereto.

Therefore, other implementations, other embodiments, and/or equivalents of the claims are within the scope of the following claims.

What is claimed is:

1. A semiconductor device comprising:
a lower transistor comprising a lower channel structure and a lower source/drain structure on the lower channel structure; and
an upper transistor above the lower transistor, the upper transistor comprising an upper channel structure and an upper source/drain structure on the upper channel structure,
wherein a portion of the upper channel structure overlaps the lower channel structure in a vertical direction, and another portion of the upper channel structure does not overlap the lower channel structure in the vertical direction.

2. The semiconductor device of claim 1, wherein side edges of the lower source/drain structure and vertically corresponding side edges of the upper source/drain structure are offset from each other in the horizontal direction.

3. The semiconductor device of claim 2, further comprising:
a substrate below the lower transistor;
a lower wiring line in the substrate; and
a contact structure connecting the upper source/drain structure to the lower wiring line.

4. The semiconductor device of claim 3, wherein the contact structure is extended in the vertical direction from the lower wiring line, and directly contacts the upper source/drain structure.

5. The semiconductor device of claim 4, wherein the contact structure comprises:
a through via extended in the vertical direction and connected to the lower wiring line; and
a contact pad connecting the through via to the upper source/drain structure,
wherein the contact pad is connected to a lower portion of the upper source/drain structure.

6. The semiconductor device of claim 1, wherein the semiconductor device comprises a first transistor stack, a second transistor stack, and a third transistor stack, each comprising the lower transistor and the upper transistor,
wherein the first transistor stack, the second transistor stack, and the third transistor stack are serially arranged in the horizontal direction.

7. The semiconductor device of claim 6, wherein:
a direction in which the lower channel structures and the upper channel structure are offset from each other in the first transistor stack is opposite to a direction in which the lower channel structure and the upper channel structure are offset from each other in the second transistor stack, and
a direction in which the lower channel structure and the upper channel structure are offset from each other in the third transistor stack is opposite to the direction in which the lower channel structure and the upper channel structure are offset from each other in the second transistor stack.

8. The semiconductor device of claim 7, wherein a separation distance in the horizontal direction between the upper channel structure of the first transistor stack and the upper channel structure of the second transistor stack is greater than a separation distance in the horizontal direction between the upper channel structure of the second transistor stack and the upper channel structure of the third transistor stack.

9. The semiconductor device of claim 7, wherein a separation distance in the horizontal direction between the lower channel stack of the first transistor stack and the lower channel stack of the second transistor stack is smaller than a separation distance in the horizontal direction between the lower channel stack of the second transistor stack and the lower channel stack of the third transistor stack.

10. The semiconductor device of claim 7, wherein a separation distance in the horizontal direction between the lower channel stack of the first transistor stack and the lower channel stack of the second transistor stack is smaller than a separation distance in the horizontal direction between the upper channel stack of the second transistor stack and the upper channel stack of the third transistor stack.

11. The semiconductor device of claim 7, wherein:
the first transistor stack and the second transistor stack are symmetric with respect to the vertical direction, and
the second transistor stack and the third transistor stack are symmetric with respect to the vertical direction.

12. The semiconductor device of claim 1, further comprising:
an intermediate insulating layer between the lower channel structure and the upper channel structure,
wherein a side surface of the intermediate insulation layer is slanted from the vertical direction.

13. A semiconductor device comprising:
a lower transistor comprising a lower channel structure and a lower source/drain structure on the lower channel structure; and
an upper transistor above the lower transistor, the upper transistor comprising an upper channel structure and an upper source/drain structure on the upper channel structure,
wherein side surfaces of the lower channel structure and vertically corresponding side surfaces of the upper channel structure are offset from each other in a horizontal direction, respectively.

14. The semiconductor device of claim 13, wherein:
the lower channel structure comprises a plurality of lower channel layers, and the upper channel structure comprises a plurality of upper channel layers, and
a number of the lower channel layers is smaller than a number of the upper channel layers.

15. The semiconductor device of claim 13, wherein a width of the lower channel structure is greater than a width of the upper channel structure.

16. A method of manufacturing a semiconductor device, comprising:
forming a lower transistor such that the lower transistor comprises a lower channel structure and a lower source/drain structure on the lower channel structure; and
forming an upper transistor above the lower transistor such that the upper transistor comprises an upper channel structure and an upper source/drain structure on the upper channel structure, and
wherein the lower channel structure and the upper channel structure are formed such that a portion of the upper channel structure overlaps the lower channel structure in a vertical direction, and another portion of the upper channel structure does not overlap the lower channel structure in the vertical direction.

17. The method of claim 16, wherein the lower source/drain structure and the upper source/drain structure are formed such that side edges of the lower source/drain structure and vertically corresponding side edges of the upper source/drain structure are offset from each other in the horizontal direction.

18. The method of claim 16, further comprising:
forming a substrate on which the lower transistor is formed; and
forming a contact structure connected to a lower portion of the upper channel structure.

19. The method of claim 16, further comprising:
forming a first transistor stack, a second transistor stack and a third transistor stack such that:
each of the first transistor stack, the second transistor stack and the third transistor stack comprises the lower transistor and the upper transistor,
the first transistor stack, the second transistor stack and the third transistor stack are serially arranged in the horizontal direction, and
the first transistor stack and the second transistor stack are symmetric with respect to the vertical direction, and
the second transistor stack and the third transistor stack are symmetric with respect to the vertical direction

20. The method of claim 16, wherein:
a width of the lower channel structure is greater than a width of the upper channel structure,
the lower channel structure comprises a plurality of lower channel layers, and the upper channel structure comprises a plurality of upper channel layers, and
a number of the lower channel layers is smaller than a number of the upper channel layers.
